(19) United States
(12) Patent Application Publication
(10) Pub. No.: US 2009/0167171 A1
(43) Pub. Date: Jul. 2, 2009

(54) DISPLAY DEVICE, ORGANIC LIGHT EMITTING DIODE DISPLAY AND MANUFACTURING METHOD OF THE SAME

(75) Inventors: Sun-Young Jung, Suwon-si (KR); Kwan-Hee Lee, Suwon-si (KR); Seung-Yong Song, Suwon-si (KR); Young-Seo Choi, Suwon-si (KR); Oh-June Kwon, Suwon-si (KR); Ji-Hun Ryu, Suwon-si (KR); Young-Cheol Joo, Suwon-si (KR); Eun-Ah Kim, Suwon-si (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/395,897

(22) Filed: Mar. 2, 2009

Related U.S. Application Data
(63) Continuation-in-part of application No. 12/269,287, filed on Nov. 12, 2008.

(30) Foreign Application Priority Data
Nov. 22, 2007 (KR) 2007-119755
Jul. 21, 2008 (KR) 2008-70738

(51) Int. Cl. H01J 1/62; H05K 5/02; H01J 9/24

(52) U.S. Cl. 313/504; 361/679.21; 445/25

(57) ABSTRACT

A display device includes a display panel and a fixing member fixed to the panel, the fixing member being formed of a resin material and being disposed to cover at least a portion of each surface of the display panel and increases durability of the display panel against external impact applied thereto and decreases thickness of the display device.

### CROSS-REFERENCE TO RELATED APPLICATIONS

This application is a continuation in part of application Ser. No. 12/269,287, filed on Nov. 12, 2008, which claims the benefit of Korean Patent Application Nos. 2007-119755 and 2008-70738 respectively filed in the Korean Intellectual Property Office on Nov. 22, 2007 and Jul. 21, 2008, the contents of which are incorporated herein by reference.

### BACKGROUND OF THE INVENTION

1. Field of the Invention

Aspects of the present invention relate to a display device, and more particularly, aspects of the present invention relate to a thin display device that is impact-resistant.

2. Description of the Related Art

Among various display panels for a display device, a display panel using an organic light emitting diode (OLED) has been receiving attention due to the advances of semiconductor technology. An active matrix type of OLED display using an organic light emitting diode includes a plurality of pixels arranged in a matrix form on a substrate and thin film transistors (TFT) disposed at each of the pixels, such that each of the pixels is independently controlled through the thin film transistors. Since such an OLED display can be small and light weight, the active matrix OLED display can be used in small-sized and mobile electronic devices, such as cellular phones, personal digital assistants (PDAs), and portable multimedia players (PMPs). Such an OLED display must have a small volume for superior portability while having high impact-resistance.

### SUMMARY OF THE INVENTION

Aspects of the present invention provide a display device of which thickness can be reduced while having excellent durability.

In addition, aspects of the present invention provide an organic light emitting diode (OLED) display that can prevent damage of a panel assembly by increasing mechanical strength with respect to external impact, and a manufacturing method thereof.

According to aspects of the present invention, a display device includes a display panel and a fixing member that is fixed to the display panel, the fixing member being formed of a resin material and being disposed to cover at least a portion of each surface of the display panel. According to aspects of the present invention, the fixing member may be made of a resin material.

According to aspects of the present invention, at least a portion of the fixing member, disposed to cover a light emitting surface of the display panel may be transparent.

According to aspects of the present invention, the fixing member may include a first portion disposed to cover a first surface of the display panel; and a second portion disposed to cover a second surface of the display panel, wherein the upper portion and the lower portion of the fixing member are sealed outside of a periphery of the display panel by thermal compression.

According to aspects of the present invention, the thicknesses of the upper and lower portions of the fixing member may be less than 0.6 mm.

According to aspects of the present invention, the fixing member can be made of plastic or silicon or a polarizing film.

According to aspects of the present invention, the display panel may include a substrate and an encapsulation substrate that are disposed to face each other, and the substrate may include an extension portion that extends beyond the encapsulation substrate and a flexible printed circuit board may be disposed on the extension portion.

According to aspects of the present invention, the flexible printed circuit board may be electrically connected to an integrated circuit chip that is disposed on the extension portion, and the flexible printed circuit board may be extended from the substrate.

According to aspects of the present invention, the fixing member may cover at least a portion of the flexible printed circuit board.

According to aspects of the present invention, an OLED display includes a panel assembly having a display area and a fixing member, the fixing member being disposed to cover at least a portion of each surface of the panel assembly.

According to aspects of the present invention, the panel assembly can be formed in a hexahedral shape and the fixing member may cover the six surfaces of the panel assembly.

According to aspects of the present invention, the fixing member may include a first cover portion that corresponds to the rear surface of the panel assembly, four of second cover portions respectively corresponding to the side surfaces of the panel assembly, and a third cover portion corresponding to the front surface of the panel assembly. According to aspects of the present invention, the first cover portion, the second cover portions, and the third cover portion may be integrally formed, and each cover portion may be bent toward an adjacent cover portion.

According to aspects of the present invention, the OLED display may further include a pad area, and one of the second cover portions corresponding to a side of the panel assembly adjacent to the pad area may include an opening.

According to aspects of the present invention, the fixing member may include a polarization layer and an adhesive layer disposed on one side of the polarization layer.

According to aspects of the present invention, the OLED display may further include a pad area, a flexible printed circuit board disposed on the pad area, and a printed circuit board that is electrically connected to the flexible printed circuit board. The printed circuit board may be disposed on an outer surface of a portion of the fixing member that covers the rear surface of the panel assembly.

According to aspects of the present invention, the OLED display may further include a case disposed on a rear side of the panel assembly that is covered by the fixing member and a double-sided tape disposed between the fixing member and the case. According to aspects of the present invention, the printed circuit board may be disposed on a rear surface of the case.

According to aspects of the present invention, a method of manufacturing an OLED display includes: preparing a panel assembly having a display area and a pad area; mounting a flexible printed circuit board, which is connected to a printed circuit board, on the pad area; preparing a fixing member having a size capable of covering an external surface of the panel assembly; and covering the panel assembly with the fixing member.

According to aspects of the present invention, the preparing of the fixing member may include cutting a polarizing sheet to include a first cover portion corresponding to a rear surface of the panel assembly, four of second cover portions respectively corresponding to side surfaces of the panel assembly, and a third cover portion corresponding to a front surface of the panel assembly.

According to aspects of the present invention, the surrounding the panel assembly with the fixing member may include attaching the first cover to the rear surface of the panel assembly, bending the second cover portions from the first cover portion and attaching the second cover portions to the side surfaces of the panel assembly, and bending the third cover portion from one of the second cover portions and attaching the third cover portion to the front surface of the panel assembly.

According to aspects of the present invention, the method may include surrounding the panel assembly with the fixing member and combining a case to the panel assembly.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a perspective view of a display device according to an exemplary embodiment of the present invention;

FIG. 2 is a cross-sectional view of FIG. 1, taken along the line II-II;

FIG. 3 is an exploded perspective view of an organic light emitting diode (OLED) display according to an exemplary embodiment of the present invention;

FIG. 4 is a perspective view of an organic light emitting diode (OLED) display according to an exemplary embodiment of the present invention;

FIG. 5 is a perspective view of the OLED display when is assembled according to an exemplary embodiment of the present invention;

FIG. 6 is a cross-sectional view of FIG. 5, taken along the line VI-VI;

FIG. 7 is a subpixel circuit configuration diagram of a panel assembly according to aspects of the present invention;

FIG. 8 is a partial cross-sectional view of inside of a panel assembly according to aspects of the present invention;

FIG. 9 is an exploded perspective view of an OLED display according to an exemplary embodiment of the present invention;

FIG. 10 is a perspective view of the OLED display of FIG. 9 when assembled according to an exemplary embodiment of the present invention;

FIG. 11 is a cross-sectional view of FIG. 10, taken along the line XI-XI; and

FIG. 12 is a schematic diagram of a drop jig used in a drop impact resistance test.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures. As those skilled in the art would realize, the described embodiments may be modified in various different ways, all without departing from the spirit or scope of the present invention. Accordingly, the drawings and description are to be regarded as illustrative in nature and not restrictive.

In the drawings, the thickness of layers, films, panels, regions, etc., are exaggerated for clarity. It will be understood that when an element such as a layer, film, region, or substrate is referred to as being “on” or “disposed on” another element, it can be directly on the other element or intervening elements may also be present. In contrast, when an element is referred to as being “directly on” another element, there are no intervening elements present. Throughout this specification and the claims that follow, when it is described that an element is “coupled” or “electrically coupled” to another element, the element may be directly coupled to the other element or coupled through a third element. In addition, unless explicitly described to the contrary, the word “comprise” and variations such as “comprises” or “comprising” will be understood to imply the inclusion of stated elements but not the exclusion of any other elements.

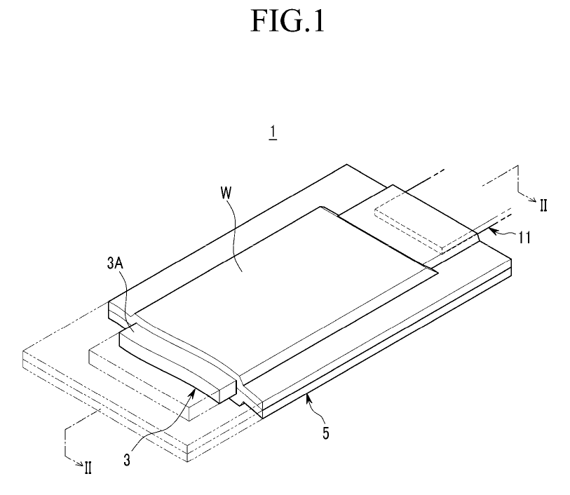

FIG. 1 is an exploded perspective view of a display device 1 according to an exemplary embodiment of the present invention. Referring to FIG. 1, the display device 1 includes a display panel 3 to display an image and a fixing member 5. An organic light emitting display panel can be used as the display panel 3. According to aspects of the present invention, other display panels, for example, a liquid crystal display panel, may be used.

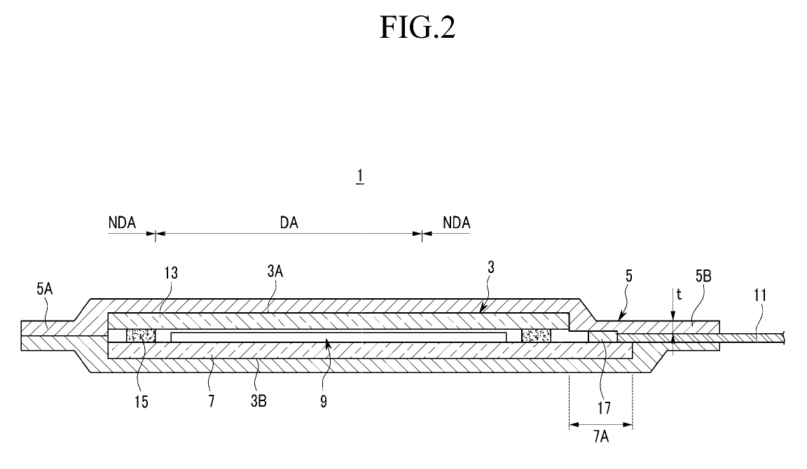

The display panel 3 includes pixels (not shown) arranged in a matrix format on a substrate 7 (see FIG. 2). Here, the pixel is a basic unit by which an image is displayed. For example, an active OLED display includes an organic light emitting unit 9 (see FIG. 2) on the substrate 7, and the organic light emitting unit 9 includes an OLED of which pixels emit light to display an image and a thin film transistor for driving the OLED.

The display panel 3 is electrically connected to a printed circuit board (PCB) (not shown) through a flexible printed circuit board (FPCB) 11, and an electric signal is input to a data line and a gate line of the thin film transistor in the PCB so that the thin film transistor is driven by the signal. In the PCB, electronic elements are provided for processing driving signals. The FPCB 11 is extended from the display panel 3 without surrounding the display panel 3.

The fixing member 5 fixes the display panel 3 and internal parts of the display panel 3 while surrounding them. A fixing member 5 surrounds the entire body of the display panel 3 while coving a light emitting surface 3A of the display panel 3. The fixing member 5 is formed of a resin material, and particularly a window portion W that covers the light emitting surface 3A may be formed of a transparent resin material for transmitting light emitted from the display panel 3. For example, the fixing member 5 can be formed of plastic or silicon. Aspects of the present invention provide that the display panel 3 may be a double-emission display panel such that light is emitted from both sides thereof. In such case, the window portion W may be provided on both sides of the fixing member 5. Further, the fixing member 5 need not surround the entire display panel 3, but may only cover portions of the sides of the display panel 3. And, the fixing member 5 may be a polarizing film.

FIG. 2 is a cross-sectional view of FIG. 1 taken along the line II-II. Referring to FIG. 2, the display panel 3 includes the substrate 7, an encapsulation substrate 13, and a sealing member 15. The substrate 7 may be made of an insulating material or a metallic material. As the insulating material, glass or plastic may be used. As the metallic material, steel use stainless (SUS) may be used.

The display panel 3 includes a light emitting area DA for emitting light and a non-light emitting area NDA disposed at the periphery of the light emitting area DA. Corresponding to the light emitting area DA, an organic light emitting unit 9, which includes a plurality of OLEDs and thin film transistors for respectively driving the OLEDs, is formed in the substrate 7. Corresponding to the non-light emitting area NDA, wire patterns (not shown) elongated in the light emitting area DA are located in the substrate 7.

In further detail, the substrate 7 includes an extension portion 7A that is protruded compared to the encapsulation substrate 13, and the wire patterns are electrically connected to an integrated circuit chip 17 and a flexible printed circuit board 11 in the extension portion 7A.

The encapsulation substrate 13 is disposed to face the substrate 7, and the substrate 7 and the encapsulation substrate 13 are combined by the sealing member 15 disposed between edges of the substrate 7 and the encapsulation substrate 7. The encapsulation substrate 13 can be made of transparent glass. However, this is not restrictive and materials of the substrate and the encapsulation substrate can be varied in accordance with a light emission direction of the OLED display.

The sealing member 15 can be formed in the non-light emitting area NDA of the substrate 7. Therefore, the encapsulation substrate 13 seals the light emitting unit 9 formed on the substrate 7 between the substrate 7 and the encapsulation substrate 13.

The fixing member 5 is formed to surround the display panel 3. Here, the flexible printed circuit board 11 connected in the extension portion 7A of the substrate 7 is disposed in parallel with the substrate 7, and the fixing member 5 surrounds the display panel 3 and a part of the integrated circuit chip 17 and a part of the flexible printed circuit board 11.

As shown in FIG. 2, the fixing member 5 has a predetermined thickness t and is separately disposed on an upper or first surface 3A and a lower or second surface 3B of the display panel 3. The fixing member 5 may fix, or be coupled to, the display panel 3 by thermal compression on edges 5A and 5B. Here, the thickness t of the fixing member 5 can be less than 0.6 mm. With such a structure, the fixing member 5 is similar to a plastic coating over the entire body of the display panel 3 so that the thickness of the display device 1 can be reduced.

In addition, the integrated circuit chip 17 and the like are provided inside the fixing member 5 so as to not be exposed to the outside; and accordingly, the integrated circuit chip 17 can be protected from an interference of an external signal.

According to aspects of the present invention, the display device 1 can be applied to a frame that displays a given amount of a motion picture or may be applied to a book that can at least partially display an image. According to aspects of the present invention, the display panel surrounds the entire display panel instead of a case, and therefore the display panel can be safely protected from external impact while minimizing the thickness of the display device. Here, the case is a fixing member made of metal for receiving the display panel and various parts. In addition, a thin display device can be applied to a product such as a frame or a book.

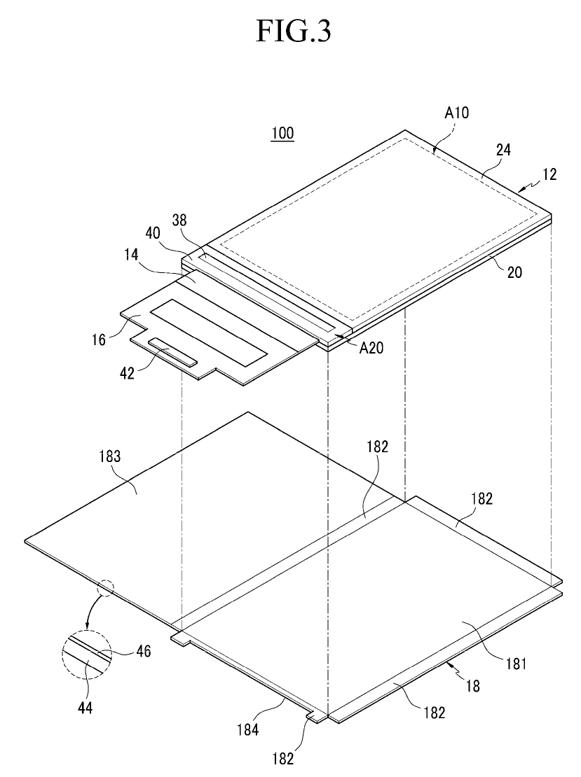

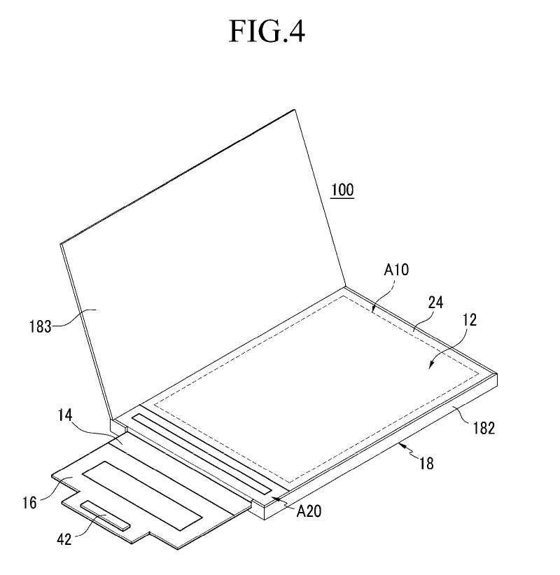

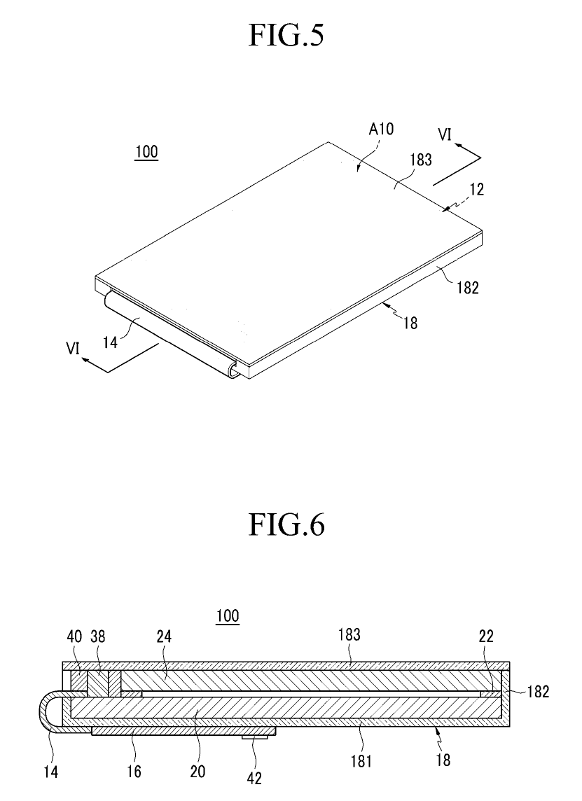

FIG. 3 and FIG. 4 show exploded perspective views of an OLED display according to an exemplary embodiment of the present invention, FIG. 5 is a perspective view of an OLED display according to aspects of the present invention, and FIG. 6 is a cross-sectional view of FIG. 5, taken along the line VI-VI.

Referring to FIG. 3 to FIG. 6, an OLED display 100 includes a panel assembly 12, a printed circuit board 16, and a fixing member 18. The panel assembly 12 includes a display area A10 and a pad area A20, and displays an image in the display area A10. The printed circuit board 16 is electrically connected to the panel assembly 12 through a flexible printed circuit board 14, and the fixing member 18 surrounds front, rear and side surfaces of the panel assembly 12.

The panel assembly 12 includes a first substrate 20 and a second substrate 24 that is smaller than the first substrate 20 and of which edges are attached to the first substrate 20 by a seal frit 22 (refer to FIG. 6). The display area A10 is located in an area where the first and second substrates 20 and 24 are overlapped in an internal side of the seal frit 22, and the pad area A20 is located on the first substrate 20 in an external side of the seal frit 22.

A plurality of subpixels are disposed in a matrix format in the display area A10 of the first substrate 20, and a scan driver (not shown) and a data driver (not shown) for driving the subpixels are disposed between the display area A10 and the seal frit 22 or in the external side of the seal frit 22. A plurality of pad electrodes (not shown) is disposed in the pad area A20 of the first substrate 20 and transmits electric signals to the scan and data drivers.

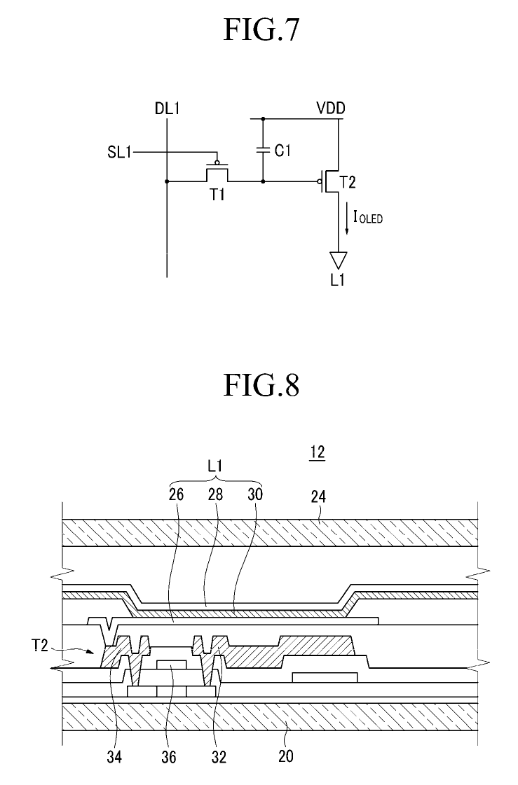

FIG. 7 shows a subpixel circuit configuration diagram of the panel assembly of FIG. 3, and FIG. 8 is an enlarged cross-sectional view of inner space of the panel assembly of FIG. 3. Referring to FIG. 7 and FIG. 8, the subpixel of the panel assembly 12 is formed of an OLED L1 and a driving circuit unit. The OLED L1 includes an anode (hole injection electrode) 26, an organic emission layer 28, and a cathode (electron injection electrode) 30, and the driving circuit unit includes at least two thin film transistors T1 and T2 and at least one storage capacitor C1. The thin film transistor may include a switching transistor T1 and a driving transistor T2.

The switching transistor T1 is connected to a scan line SL1 and a data line DL1 and transmits a data voltage input to the data line DL1 according to a switching voltage input to the scan line SL1 to the driving transistor T2. The storage capacitor C1 is connected to the switching transistor T1 and a power source line VDD and stores a voltage difference of a voltage transmitted from the switching transistor T1 and a voltage applied to the power source line VDD.

The driving transistor T2 is connected to the power source line VDD and the storage capacitor C1 and supplies an output current IOLED that is proportional to the square of a voltage difference of a voltage stored in the storage capacitor C1 and a threshold voltage to the OLED L1, and the OLED L1 emits light according to the output current IOLED. The driving transistor T2 includes a source electrode 32, a drain electrode 34, and a gate electrode 36, and the anode 26 of the OLED L1 may be connected to the drain electrode 34 of the driving transistor T2. As shown in FIGS. 7 and 8, the anode 26 of the OLED L1 is electrically connected to the drain electrode 34 of the driving transistor T2. A configuration of the subpixel is not limited to the above-described example, and can be variously modified.

Referring back to FIG. 3 to FIG. 6, the second substrate 24 is bonded with the first substrate 20 at a predetermined distance by the seal frit 22 in order to protect the driving circuit units and the OLEDs formed on the first substrate 20 from an outer environment. A moisture absorbing member may be provided inside the second substrate 24.

On the pad area A20 of the panel assembly 12, an integrated circuit chip 38 is mounted by a chip on glass (COG) method and a flexible printed circuit board 14 is mounted by a chip on film (COF) method. A protective layer 40 is formed around the integrated circuit chip 38 and the flexible printed circuit board 14 to cover pad electrodes (not shown) formed in the pad area A20 for protection. In the printed circuit board (PCB) 16, electron elements (not shown) are provided for processing driving signals and a connector 42 is provided for transmitting external signals to the printed circuit board (PCB) 16.

A fixing member 18 is formed in a structure that surrounds not only the display area A10 of the panel assembly 12 but also front, and rear, and side surfaces of the panel assembly 12. That is, the fixing member 18 is formed to substantially surround six surfaces of the panel assembly 12. Such a fixing member 18 reduces reflection of external light and functions as an impact-resistant member to reduce the amount of impact transmitted to the panel assembly 12 by protecting the panel assembly 12 from the external environment.

The fixing member 18 is formed of a polarization layer 44 (refer to FIG. 3) that has a polarization function and an adhesive layer 46 (refer to FIG. 3) that is formed on one side of the polarization layer 44 and disposed to face the panel assembly 12, which adheres the polarization layer 44 to the panel assembly 12. The overall fixing member 18 or a portion that corresponds to the display area A10 has light transmittance, and is made of a polymer resin material or a silicon resin material.

The fixing member 18 made of polymer resin can be easily bent so that a film sheet can be cut in a size that can covers portions of at least six sides of the panel assembly 12 and the cut fixing member 18 can be bent and attached to the panel assembly 12.

As shown in FIG. 3, the cut fixing member 18 cut for each sides of the panel assembly 12 includes a first cover portion 181 that corresponds to a rear surface of the first substrate 20, four of second cover portions 182 that respectively correspond to side surfaces of the first and second substrates 20 and 24, and a third cover portion 183 that corresponds to front surfaces of the second substrates and the protective layer 40. The cover portions 181, 182, and 183 are integrally formed.

Among the four of the second cover portions 182, one cover portion 182 that corresponds to the pad area A20 can have an opening 184 through which the flexible printed circuit board 14 can pass.

As shown in FIG. 4, the first cover portion 181 is attached to the rear surface of the first substrate 20, the four of the second cover portions 182 are bent from the first cover portion 181 to attach the second cover portions 182 to the side surfaces of the first and second substrates 20 and 24, and the third cover portion 183 is bent from one of the second cover portions 182 to attach the third cover portion 183 to the front surfaces of the second substrate 24 and the protective layer 40.

In FIG. 3, the four second cover portions 182 are respectively located at four edges of the first cover portion 181, and the third cover portion 183 is connected to one of the second cover portions 182. In this case, ends of the second cover portions 182 match edges of the panel assembly 12, and the fixing member 18 can surround the panel assembly 12 without overlapping other cover portions 181, 182, or 183.

A shape of the fixing member 18 before being attached to the panel assembly 12 is not restrictive, and it can be variously modified. However, when forming the fixing member 18, a contiguous portion of the fixing member preferably completely covers the display area A10. In addition, the fixing member 18 can be overlap other portions 181, 182, and 183 of the fixing member 18, preferably not in the display area A10, when attached to the panel assembly 12.

Referring back to FIG. 3 to FIG. 6, a manufacturing method of the OLED display 100 having the above-described configuration can include a first process for making the panel assembly 12 by forming OLEDs and driving circuit units on the first substrate 10 and attaching the first and second substrates 10 and 20 by using a seal frit 22, a second process for mounting the flexible printed circuit board 14 that is connected to printed circuit board 16 on the pad area A20 of the first substrate 10, a third process for preparing the fixing member 18 in size that can surround outer surfaces of the panel assembly 12, and a fourth process for surrounding the panel assembly 12 with the fixing member 18.

After the fourth process, the flexible printed circuit board 14 is bent to the rear side of the first cover portion 181 to locate the printed circuit board (PCB) 16 in the rear surface of the first cover portion 181 of the fixing member 18. That is, the printed circuit board (PCB) 16 is located to face the rear surface of the first substrate 20, and the fixing member 18 is disposed therebetween.

As described, the OLED display 100 according to aspects of the present invention is formed in a structure that surrounds six sides of the panel assembly 12 by attaching the fixing member 18 to the panel assembly 12. Unlike a metallic fixing member, the polymer resin fixing member 18 is not broken or damaged by external impact and has excellent impact-absorbing capability. Therefore, when the OLED display 100 is dropped so that external impact is applied thereto, the fixing member 18 absorbs the impact so that the panel assembly 12 can be prevented from being damaged.

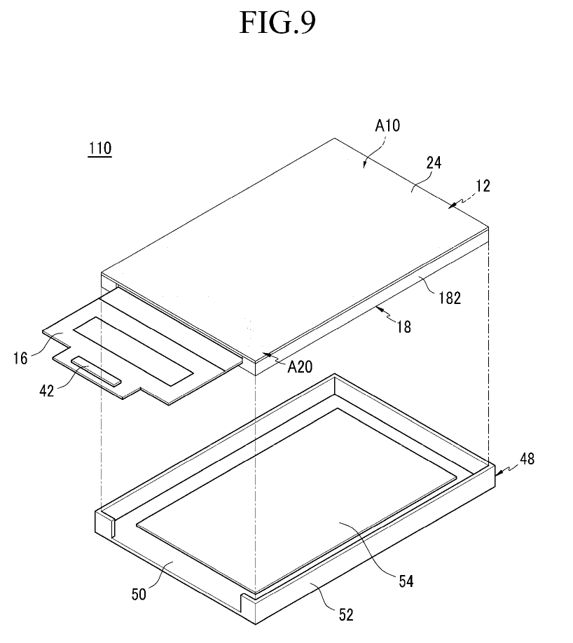

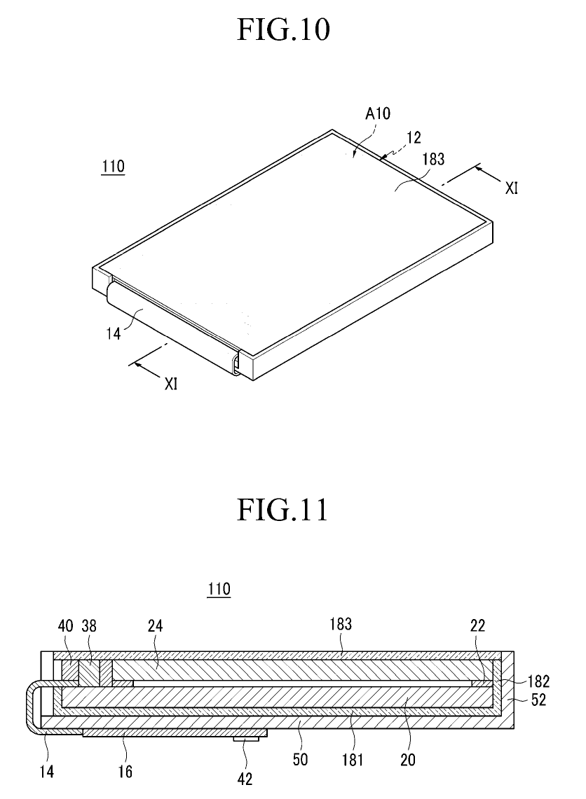

FIG. 9 is an exploded perspective view of an OLED display, FIG. 10 is a perspective view of an OLED display when it is assembled, and FIG. 11 is a cross-sectional view of FIG. 10, taken along the line XI-XI. Referring to FIG. 9 to FIG. 11, an OLED display 110 has the same configuration as the OLED display as described above except in that a case 48 is disposed on a rear side of a panel assembly 12 that is surrounded by a fixing member 18. In the following description, the same reference numerals are used for the same elements as described above.

The case 48 is formed of a bottom portion 50 on which the panel assembly 12 surrounded by the fixing member 18 is mounted and a sidewall 52 that is extended toward the panel assembly 12 from an edge portion of the bottom portion 50. The sidewall 52 is disposed about the periphery of the bottom portion 50 except for a portion thereof in which the flexible printed circuit board 14 extends from the panel assembly 12 and is bent. A double-sided adhesive tape 54 is disposed on the bottom portion 50 of the case 48 between the first cover portion 181 of the fixing member 18 attached to the rear surface of first substrate 20 to fix the panel assembly 12 surrounded by the fixing member 18 to the case 48.

A structure of the case 48 is not limited thereto, and can be variously modified. For example, the case 48 may include a flange being one or several of various shapes to enhance strength at the edge portion of the bottom unit 50, at which the flexible printed circuit board is bent, or may form a hemming sidewall by bending the sidewall 52 several times to increase the mechanical strength thereof.

The case 48 may be formed of metal having excellent strength and rigidity, such as stainless steel, cold rolled steel, aluminum, an aluminum alloy, a nickel alloy, and the like. Alternatively, the case 48 may be formed of a synthetic resin having excellent impact absorption/dispersion properties. For example, the case 40 may be formed of a polymer-based engineering plastic, such as polycarbonate.

The OLED display 110 can be manufactured by making the OLED display previously described, locating the case 48 in the rear side of the panel assembly 12 surrounded by the fixing member 18, and combining the panel assembly 12 and the case 48 by using the double-sided adhesive tape 54.

12 test samples of a Comparative Example OLED display in which a fixing member was attached to a display area having the diagonal length of 60.96 mm (2.4-inch) of a panel assembly and to which a case was directly combined to the panel assembly were made and tested, and 12 test samples for an Exemplary OLED display as described above—in which a fixing member surrounds six sides of a panel assembly without using a case were made and tested.

In the Comparative Example OLED display, the case was formed in the same shape of the case 48 of FIG. 9 to FIG. 11 and was made of stainless steel.

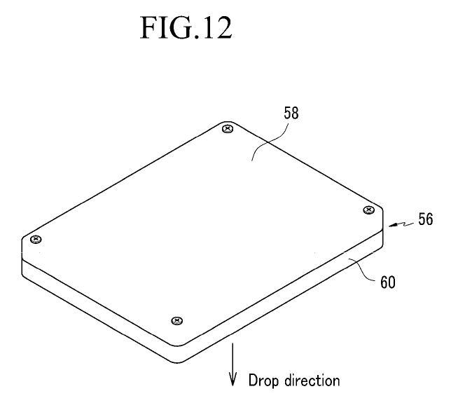

The test samples were mounted in a drop jig, and the drop jig was dropped from a height of 1.5 m to determine damage to the panel assembly. FIG. 12 is a schematic diagram of a drop jig used for the drop test. A drop jig 56 is formed of an upper case 58 and a lower case 60 that are coupled by screws, and the OLED displays were individually mounted inside the drop jig 56 to direct the display area downward (i.e. the top surface of the second substrate 24 covered by the third cover portion 183 was oriented to face the drop direction of the drop jig 56).

The following Table 1 shows drop test results of the Comparative Example OLED display and the Exemplary OLED.

TABLE 1

| | | Seal | Seal | Seal | Seal |
|---|---|---|---|---|---|
| | | frit 1 | frit 2 | frit 3 | frit 4 |
| Comparative | Test sample No. 1 | 1 | 1 | 1 | 1 |
| Example | Test sample No. 2 | 1 | 1 | 1 | 1 |
| | Test sample No. 3 | 1 | 1 | 1 | 1 |
| Exemplary | Test sample No. 1 | 2 | 1 | 7 | 5 |
| OLED | Test sample No. 2 | 3 | 2 | 2 | 3 |
| | Test sample No. 3 | 4 | 4 | 5 | 2 |

In the Table, the 12 Comparative Example OLED test samples and the 12 Exemplary OLED test samples are classified into four types of the seal frit. The four types of the seal frits each had the same bismuth (Bi)-based composition, and each of four types of the seal frits was made under a different process condition.

In addition, the numerical values in the Table indicate test orders that show damage of the panel assembly in a series of drop test. That is, the numerical value “1” indicates than the panel assembly was damaged in the first test, and “2” indicates that the panel assembly was damaged in the second test, etc.

As shown in the Table, the panel assemblies in the Comparative Example OLED test samples were all damaged in the first drop test, whereas the panel assemblies of the Exemplary OLED test samples more often passed the drop test than the Comparative Example OLED test samples, excluding one case. Thus, 11 of the 12 Exemplary OLED test samples survived one fall in the drop jig 56 from 1.5 m.

The results indicate that the case can be easily deformed by external impact and the deformation of the case is directly transmitted to the panel assembly in the Comparative Example OLED display, and that the fixing member that surrounded the Exemplary OLED panel assemblies effectively reduced the amount of impact transmitted to the panel assembly. Therefore, the OLED display according to aspects of the present invention can decrease damage of the panel assembly due to external impact by increasing mechanical strength of the panel assembly with the fixing member.

Since the OLED display according to aspects of the present invention has a fixing member disposed to surround the panel assembly, the fixing member absorbs most of the external impact when the OLED display is dropped so that the external impact is applied thereto and thus the damage of the panel assembly can be decreased. Therefore, the OLED display according to aspects of the present invention can provide excellent drop reliability by increasing mechanical strength to resist external impact.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A display device, comprising:
a display panel; and
a fixing member fixed to the display panel, the fixing member being formed of a resin material and being disposed to cover at least a portion of each surface of the display panel.

2. The display device of claim 1, wherein at least a portion of the fixing member disposed to cover a light emitting surface of the display panel is transparent.

3. The display device of claim 1, wherein the fixing member comprises:
a first portion disposed to cover a first surface of the display panel; and
a second portion disposed to cover a second surface of the display panel, the second surface being opposite the first surface,
wherein the first portion and the second portion of the fixing member are sealed outside of a periphery of the display panel by thermal compression.

4. The display device of claim 3, wherein the thicknesses of each of the first and second portions of the fixing member is less than 0.6 mm.

5. The display device of claim 1, wherein the fixing member is made of plastic, silicon, and/or a polarizing film.

6. The display device of claim 1, wherein the display panel comprises:
a substrate and an encapsulation substrate disposed to face each other, the substrate including an extension portion that extends beyond an edge of the encapsulation substrate; and
a flexible printed circuit board disposed on the extension portion.

7. The display device of claim 6, further comprising:
an integrated circuit chip disposed on the extension portion,
wherein the flexible circuit board is electrically connected to the integrated circuit chip and extends from the substrate.

8. The display device of claim 6, wherein the fixing member surrounds at least a portion of the flexible printed circuit board.

9. The display device of claim 3, further comprising:
a flexible printed circuit board electrically connected to the display panel and extending therefrom between the first and second portions of the fixing member.

10. The display device of claim 9, wherein the first and second portions of the fixing member are sealed about the flexible printed circuit board.

11. The display device of claim 1, further comprising:
an organic light emitting element disposed between the substrate and the encapsulation substrate; and
a sealing member disposed between the substrate and the encapsulation substrate to seal the organic light emitting element therein.

12. An organic light emitting diode (OLED) display, comprising:
a panel assembly having a display area; and
a fixing member, the fixing member being disposed to cover at least a portion of each surface of the panel assembly.

13. The OLED display of claim 12, wherein the panel assembly has a hexahedral shape, and the fixing member covers at least a portion each of the six surfaces of the panel assembly.

14. The OLED display of claim 12, wherein the fixing member comprises:
a first cover portion disposed to cover a rear surface of the panel assembly;
four second cover portions respectively corresponding to the side surfaces of the panel assembly; and
a third cover portion corresponding to the front surface of the panel assembly.

15. The OLED display of claim 14, wherein each of the second cover portions is bent from the first cover unit toward the front surface of the panel assembly, and the third cover portion is bent from one of the second cover portions to cover the front surface of the panel assembly.

16. The OLED display of claim 14, wherein the panel assembly comprises:
a pad area,
wherein one of the second cover portions, which corresponds to a side of the display panel adjacent to the pad area, includes an opening to expose a portion of the side of the display panel adjacent to the pad area.

17. The OLED display of claim 12, wherein the fixing member comprises:
a polarization layer, and
an adhesive layer disposed on one side of the polarization layer.

18. The OLED display of claim 17, wherein the adhesive layer adheres the fixing member the display panel.

19. The OLED display of claim 12, further comprising:
a pad area;
a flexible printed circuit board connected to the pad area; and
a printed circuit board electrically connected to the flexible printed circuit board,
wherein the printed circuit board is disposed on an outer surface of a portion of the fixing member disposed to cover the rear surface of the panel assembly.

20. The OLED display of claim 12, comprising:
a case disposed on a rear surface of the panel assembly that is covered by the fixing member; and
a double-sided tape disposed between the fixing member and the case.

21. The OLED display of claim 20, further comprising:
a pad area;
a flexible printed circuit board that is connected to the pad area; and
a printed circuit board that is electrically connected to the flexible printed circuit board,
wherein the printed circuit board is disposed on between the panel assembly and the case.

22. A method for manufacturing an organic light emitting diode (OLED) display, comprising:
preparing a panel assembly having a display area and a pad area;
mounting a flexible printed circuit board on the pad area, the flexible circuit board being connected to a printed circuit board;
preparing a fixing member to have a size capable of covering an external surface of the panel assembly; and
covering the panel assembly with the fixing member.

23. The method of claim 22, wherein the preparing of the fixing member comprises:
cutting a polarizing sheet to include a first cover portion corresponding to a rear surface of the panel assembly, four of second cover portions respectively corresponding to side surfaces of the panel assembly, and a third cover portion corresponding to a front surface of the panel assembly.

24. The method of claim 23, wherein the covering of the panel assembly with the fixing member comprises:
attaching the first cover to the rear surface of the panel assembly,
bending the second cover portions from the first cover portion and attaching the second cover portions to the side surfaces of the panel assembly, and
bending the third cover portion extended from one of the second cover portions and attaching the third cover portion to the front surface of the panel assembly.

25. The method of claim 22, comprising attaching a case to the panel assembly.

26. A method for manufacturing a display device, comprising:
preparing a panel assembly having a display area and a pad area;
mounting a flexible printed circuit board on the pad area, the flexible circuit board being connected to a printed circuit board;
disposing the panel assembly and the mounted flexible circuit board between a first fixing member and a second fixing member; and
thermally compressing the first fixing member and the second fixing member outside of a periphery of the panel assembly to seal the panel assembly therein.
